(19) United States
(12) Patent Application Publication
(10) Pub. No.: US 2024/0145621 A1
(43) Pub. Date: May 2, 2024

(54) VERTICAL LED CHIP STRUCTURE, METHOD OF MANUFACTURING SAME AND LIGHT-EMITTING DEVICE

(71) Applicant: Tianjin Sanan Optoelectronics Co., Ltd., Tianjin (CN)

(72) Inventors: Shengnan LIU, Tianjin (CN); Weifan KE, Tianjin (CN); Jiayu LIU, Tianjin (CN); Pengjie HU, Tianjin (CN); Xiao BAI, Tianjin (CN)

(73) Assignee: Tianjin Sanan Optoelectronics Co., Ltd., Tianjin (CN)

(21) Appl. No.: 18/476,227

(22) Filed: Sep. 27, 2023

(30) Foreign Application Priority Data
Oct. 31, 2022 (CN) 202211343672.3

(51) Int. Cl. H01L 33/00; H01L 25/075; H01L 33/06; H01L 33/14; H01L 33/22; H01L 33/30; H01L 33/40; H01L 33/44

(52) U.S. Cl. CPC H01L 33/0066; H01L 25/0753; H01L 33/0093; H01L 33/0095; H01L 33/06; H01L 33/145; H01L 33/22; H01L 33/30; H01L 33/405; H01L 33/44; H01L 2933/0016; H01L 2933/0025

(57) ABSTRACT

A vertical LED chip structure, a method of manufacturing the same, and a light-emitting device are provided. After an epitaxial structure is bonded to a substrate, the epitaxial structure is etched first to form a first mesa. After the first mesa is formed, the epitaxial structure is continuously etched at the first mesa until the epitaxial structure is etched through and a reflective layer is exposed, and a second mesa is formed. A protective layer is formed on a surface of the structure where the first mesa and the second mesa are formed. The protective layer covers the exposed reflective layer at the second mesa, protects the epitaxial structure and the reflective layer, and protects a side wall of the epitaxial structure and the reflective layer from being corroded by a processing solution after a back surface of the substrate is polished.

### CROSS-REFERENCE TO RELATED APPLICATION

This application claims the priority benefit of China application serial no. 202211343672.3, filed on Oct. 31, 2022. The entirety of the above-mentioned patent application is hereby incorporated by reference herein and made a part of this specification.

### BACKGROUND

### Technical Field

The disclosure relates to the technical field of semiconductor elements and devices, and in particular, to a vertical LED chip structure, a method of manufacturing the same, and a light-emitting device.

### Description of Related Art

In terms of the light-emitting diode (LED) structure, gallium arsenide (GaAs)-based LEDs may be divided into the formal structure, the flip-chip structure, and the vertical structure. Compared to the traditional GaAs-based LED formal structure, the vertical structure has the following advantages, such as good heat dissipation, the ability to carry large currents, high light-emitting intensity, low power consumption, and long service life. Therefore, the vertical structure is widely used in various fields, such as general lighting, landscape lighting, special lighting, and automotive lighting. The vertical structure has become a promising solution for a generation of high-power GaAs-based LEDs and is receiving increasing attention and being increasingly studied in the industry.

The space between the first mesas of the light-emitting epitaxial structures of the conventional vertical structure LED chips is the dicing lane region, and in order to facilitate subsequent dicing, the second mesa is formed in the dicing lane region most of the time. In the prior art, after the first mesa is formed, a protective layer is formed first, and then the second mesa is formed. Herein, the subsequently formed second mesa forms an exposed light-emitting epitaxial structure and a metal structure (e.g., a reflective layer). This causes the polishing slurry to come into contact with the exposed light-emitting epitaxial structure and the metal structure when the substrate is subsequently polished and thinned during backside metallization to form an electrode. As a result, the LED chip is damaged, and the reliability of the chip is affected.

In view of the above, it is necessary to provide a solution that can prevent the processing slurry from damaging the LED chip during the processing of the back surface of the substrate.

### SUMMARY

In view of the abovementioned defects in the formation process of a vertical LED chip in the prior art, the disclosure provides a vertical LED chip structure, a method of manufacturing the same, and a light-emitting device with an aim to solve the abovementioned one or more problems.

An embodiment of the disclosure provides a method of fabricating a vertical LED chip structure, and the method includes the following steps.

An epitaxial structure including a first conductivity type semiconductor layer, a light-emitting layer, and a second conductivity type semiconductor layer stacked in sequence is fabricated.

A substrate having a front surface and a back surface opposite to the front surface is provided.

The epitaxial structure is bonded to the front surface of the substrate. A side where the second conductivity type semiconductor layer is located is bonded to the substrate.

The epitaxial structure is etched for a first time at a position corresponding to a dicing region to form a first mesa, and side walls of the first conductivity type semiconductor layer and the light-emitting layer are exposed. A surface of the first mesa is the second conductivity type semiconductor layer.

The epitaxial structure is etched for a second time at the first mesa to form a second mesa, and a side wall of the second conductivity type semiconductor layer is exposed.

A protective layer is formed on the surface and a side wall of the first mesa, a surface and a side wall of the second mesa, and a surface of the epitaxial structure.

In addition, a back electrode electrically connected to the second conductivity type semiconductor layer is formed on the back surface of the substrate.

Optionally, the preparation of the epitaxial structure further includes the following steps.

A temporary substrate is provided.

The first conductivity type semiconductor layer, the light-emitting layer, and the second conductivity type semiconductor layer are deposited in sequence on a front surface of the temporary substrate.

A second electrode including a current blocking layer and a transparent conductive layer adjacent to the second conductivity type semiconductor layer is formed above the second conductivity type semiconductor layer, and a reflective layer is formed above the current blocking layer and the transparent conductive layer. The transparent conductive layer is formed in a through hole penetrating through the current blocking layer and is in contact with the second conductivity type semiconductor layer.

In addition, a bonding layer is formed above the reflective layer.

Optionally, the formation of the back electrode on the back surface opposite to the front surface of the substrate further includes the following steps.

A polishing slurry is applied to the back surface of the substrate, and the back surface of the substrate is masked and thinned.

The thinned substrate is cleaned with deionized water and dried.

In addition, a metal layer is deposited on the back surface of the substrate to form the back electrode.

Another embodiment of the disclosure further provides a vertical LED chip structure including a substrate, an epitaxial structure, a first mesa, a second mesa, a protective layer, and a back electrode.

The substrate has a front surface and a back surface opposite to the front surface.

The epitaxial structure is located on the front surface of the substrate and includes a first conductivity type semiconductor layer, a light-emitting layer, and a second conductivity type semiconductor layer stacked in sequence. A side where the second conductivity type semiconductor layer is located is bonded to the substrate.

The first mesa is formed in the second conductivity type semiconductor layer corresponding to a dicing region, and a surface of the first mesa is the second conductivity type semiconductor layer. The second mesa is formed in the first mesa.

The protective layer is formed on the surface and a side wall of the first mesa, a surface and a side wall of the second mesa, and a surface of the first conductivity type semiconductor layer located in the dicing region.

The back electrode is formed on the back surface of the substrate and is electrically connected to the second conductivity type semiconductor layer.

Another embodiment of the disclosure further provides a light-emitting device including the vertical LED chip structure provided by the disclosure.

As described above, the vertical LED chip structure, the method of manufacturing the same, and the light-emitting device exhibit the following beneficial effects.

In the disclosure, after the epitaxial structure is bonded to the substrate, the epitaxial structure is etched first to form the first mesa. The first mesa is formed in the second conductivity type semiconductor layer of the epitaxial structure. That is, the surface of the first mesa is the second conductivity type semiconductor layer. After the first mesa is formed, the epitaxial structure is continuously etched at the first mesa until the epitaxial structure is etched through and the substrate is exposed, and the second mesa is formed. The width of the second mesa is less than the width of the first mesa. The first mesa and the second mesa have a height difference. This structure can effectively reduce internal reflection of large-angle light in the epitaxial structure, reduce secondary absorption of light, and improve a side light extraction rate. Especially for small and medium-sized chips, the side light extraction rate may be significantly improved, while the impact of scratching and melting back on brightness can be lowered, and the overall light extraction efficiency is improved.

The protective layer is formed on the surface of the structure where the first mesa and the second mesa are formed. The protective layer covers the surface and the side wall of the first mesa, the surface and the side wall of the second mesa, and the surface of the epitaxial structure on both sides of the first mesa corresponding to the dicing region. The protective layer covers the exposed reflective layer at the second mesa and thus protects the epitaxial structure and the reflective layer. After the protective layer is formed, the backside metallization process is performed on the substrate. Herein, the protective layer protects the side wall of the epitaxial structure and the reflective layer from being corroded by the processing solution after the back surface of the substrate is polished and thinned. In this way, the integrity of the epitaxial structure is ensured, and the reliability of the chip is improved. The method provided by the disclosure does not require the addition of additional process flows and may be implemented by adjusting the process parameters of the relevant processes. Therefore, this method does not cause an increase in costs and is conducive to mass production.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1 is a schematic structural diagram illustrating formation of a protective layer after a first mesa is formed in the prior art.

FIG. 2 is a schematic structural diagram illustrating formation of a second mesa in the structure shown in FIG. 1.

FIG. 3 is a schematic flow chart illustrating a method of fabricating a vertical light-emitting diode (LED) chip structure according to Embodiment 1 of the disclosure.

FIG. 4, FIG. 5A, and FIG. 5B are schematic structural diagrams corresponding to the process of fabricating an epitaxial structure shown in FIG. 3.

FIG. 6 shows a schematic structural diagram illustrating bonding the epitaxial structure shown in FIG. 5B to a substrate.

FIG. 7 is a schematic structural diagram illustrating formation of a first electrode in the structure shown in FIG. 6.

FIG. 8 is a schematic structural diagram illustrating formation of the first mesa in the structure shown in FIG. 6.

FIG. 9 is a schematic structural diagram illustrating formation of the second mesa in the structure shown in FIG. 8.

FIG. 10 is a schematic structural diagram illustrating formation of the protective layer on a surface of the structure shown in FIG. 9.

FIG. 11 is a schematic structural diagram illustrating formation a back electrode on a back surface of the substrate having the structure shown in FIG. 10.

FIG. 12 is a schematic structural diagram illustrating a vertical LED chip structure according to Embodiment 2 of the disclosure.

FIG. 13 is a schematic structural diagram illustrating a light-emitting device according to Embodiment 3 of the disclosure.

### DESCRIPTION OF THE EMBODIMENTS

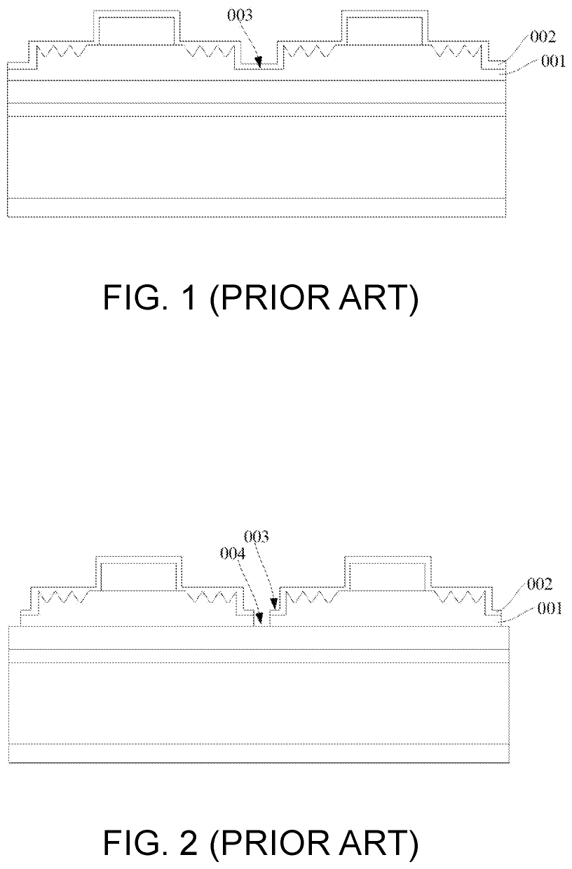

As shown in FIG. 1, in the prior art, when a vertical light-emitting diode (LED) chip is manufactured, after a first mesa 003 is formed on a light-emitting epitaxial structure 001, a protective layer 002 is formed on an exposed surface of the epitaxial structure 001. Next, as shown in FIG. 2, the light-emitting epitaxial structure 001 is continuously etched at the position of the first mesa 003 until the light-emitting epitaxial structure 001 is etched through and a second mesa 004 is formed. Herein, as shown in FIG. 2, the formation of the second mesa 004 exposes part of the light-emitting epitaxial structure 002. During the subsequent backside metallization of a substrate, a KOH solution is used most of the time to perform surface treatment on a back surface of the polished and thinned substrate. Herein, the KOH solution may cause damage to the exposed light-emitting epitaxial structure 002 and also cause damage to an exposed metal layer (e.g., a reflective layer and/or a bonding layer) of the second mesa 004, and the reliability of the chip is thus affected.

In order to solve the above problems, the disclosure provides a vertical LED chip structure, a method of manufacturing the same, and a light-emitting device. Detailed description will now be given with reference to the following embodiments and drawings.

### Embodiment 1

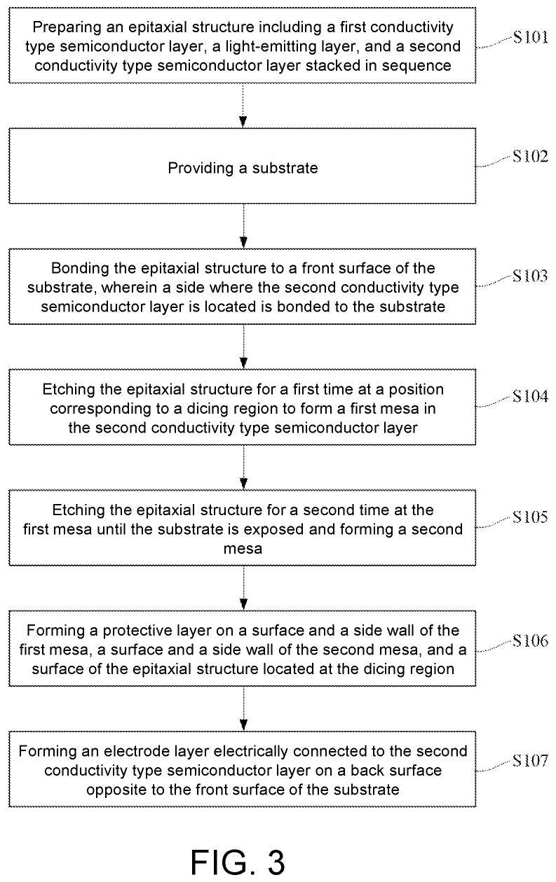

The embodiment provides a method of manufacturing a vertical LED chip structure, and as shown in FIG. 3, the method includes the following steps.

In S101, an epitaxial structure including a first conductivity type semiconductor layer, a light-emitting layer, and a second conductivity type semiconductor layer stacked in sequence is fabricated.

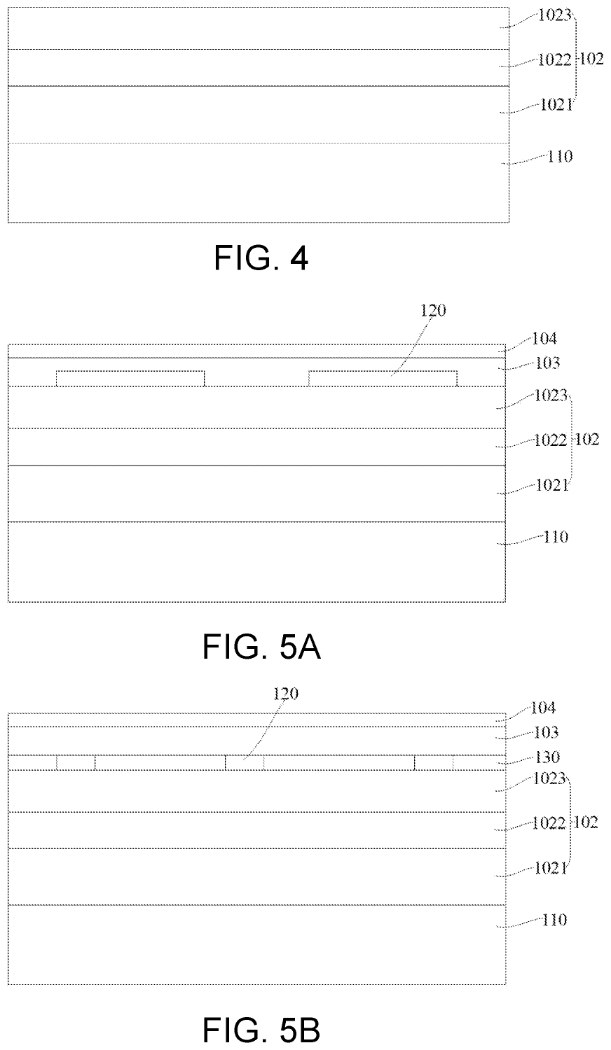

As shown in FIG. 4, first, a temporary substrate 110 is provided, and the temporary substrate 110 may be a sapphire substrate, a silicon carbide substrate, a gallium arsenide (GaAs) substrate, or other substrates suitable for growing an epitaxial layer. In this embodiment, a growth substrate is a GaAs substrate as an example.

A first conductivity type semiconductor layer 1021, a light-emitting layer 1022, and a second conductivity type semiconductor layer 1023 are deposited on the growth substrate in sequence to form an epitaxial structure 102. For instance, a chemical vapor deposition process may be used to form the first conductivity type semiconductor layer 1021, the light-emitting layer 1022, and the second conductivity type semiconductor layer 1023 in sequence on the GaAs substrate.

In this embodiment, an AlGaInP-based red light epitaxial structure is taken as an example. As an example, the first conductivity type semiconductor layer 1021 is an N-type AlGaInP layer, and the second conductivity type semiconductor layer 1023 is a P-type AlGaInP layer. A thickness of the n-type AlGaInP layer may be 0.5 μm to 3 μm. The light-emitting layer 1022 is a multi-quantum well layer including AlGaInP quantum well layers and AlGaInP quantum barrier layers that are alternately grown. The Al contents in the AlGaInP quantum well layers and the AlGaInP quantum barrier layers are different. Herein, the light-emitting layer 1022 may include 3 to 8 periods of AlGaInP quantum well layers and AlGaInP quantum barrier layers that are alternately stacked. As an example, the light-emitting layer 1022 includes 5 periods of AlGaInP quantum well layers and AlGaInP quantum barrier layers that are alternately stacked. Optionally, a thickness of the light-emitting layer 1022 may be 150 nm to 200 nm. Optionally, the second conductivity type semiconductor layer 1023 is an indium-doped p-type AlInP layer. A thickness of the p-type AlInP layer may be 0.5 μm to 3 μm.

After the abovementioned P-type AlInP layer is formed, a second electrode is formed above the P-type AlInP layer. As shown in FIG. 5, a transparent conductive layer 120 is formed above the P-type AlInP layer first. The transparent conductive layer 120 may be, for example, ITO, and the transparent conductive layer 120 acts as an ohmic contact layer. A reflective layer 103 is formed next. The reflective layer 103 is formed above the transparent conductive layer 120 and on a surface of the P-type AlInP layer outside the transparent conductive layer 120. In this way, the reflective layer 103 covers and wraps the transparent conductive layer 120 to reflect the light radiated by the light-emitting layer 1022 in all directions. Preferably, the reflective layer 103 is a total reflection mirror structure, for example, it can be a metal Ag reflection mirror.

In another optional embodiment of the disclosure, when the second electrode is formed, as shown in FIG. 5B, a current blocking layer 130 is formed above the P-type AlInP layer first. The current blocking layer 130 may be used as a dielectric layer of an ODR reflective structure and is usually a low N (refractive index) material layer, for example, it can be a transparent dielectric layer such as SiNₓ, SiO₂, Al₂O₃, MgF₂, etc. Next, as shown in FIG. 5B, a through hole is formed in the current blocking layer 130, and the transparent conductive layer 120 is formed in the through hole. The transparent conductive layer 120 may be, for example, ITO, and the transparent conductive layer 120 acts as an ohmic contact layer. The reflective layer 103 is formed next. The reflective layer 103 is formed on the current blocking layer 130 and on a surface of the P-type AlInP layer above the transparent conductive layer 120 to reflect the light radiated by the light-emitting layer 1022 in all directions. Preferably, the reflective layer 103 is a total reflection mirror structure, for example, it can be a metal Ag reflection mirror. A bonding layer 104 is formed above the reflective layer 103, and the bonding layer 104 is a metal bonding layer, such as an Au/Sn metal bonding layer.

In S102, a substrate having a front surface and a back surface opposite to the front surface is provided.

As described above, after the epitaxial structure 102 is grown on the temporary substrate 110, a substrate 101 is provided. The substrate 101 acts as a bonding substrate, that is, a permanent substrate, for bonding the abovementioned epitaxial structure 102. Optionally, the substrate 101 may be one of a Si substrate, a W/Cu substrate, and a Mo/Cu substrate. In this embodiment, the substrate is a Si substrate.

In S103, the epitaxial structure is bonded to the front surface of the substrate. A side where the second conductivity type semiconductor layer is located is bonded to the substrate.

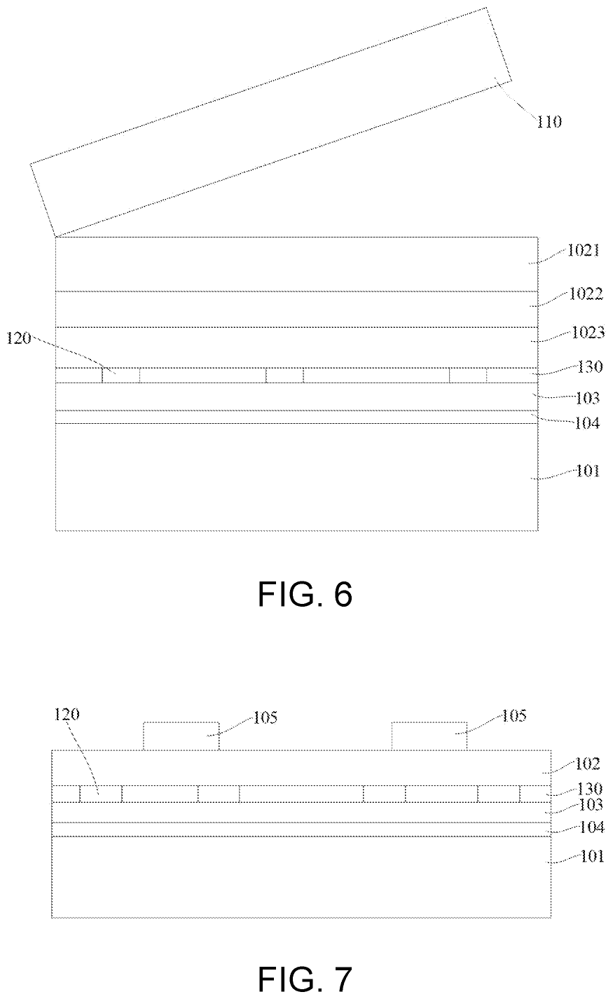

Taking the epitaxial structure in FIG. 5B as an example, as shown in FIG. 6, the bonding layer 104 of the epitaxial structure 102 is bonded to the front surface of the substrate 101. The epitaxial structure 102 and the substrate 101 may be bonded together via, for example, the high temperature bonding layer 104.

Next, as shown in FIG. 6, the temporary substrate 110 is peeled off. For instance, a laser peel-off process or wet etching may be used to peel off the temporary substrate 110 to improve the peel-off efficiency and reduce damage to the epitaxial structure 102.

After the epitaxial structure is bonded to the substrate 101 and the temporary substrate 110 is peeled off, as shown in FIG. 7, a first electrode 105 is formed on a surface of the exposed first conductivity type semiconductor layer 1021. The first electrode 105 may be a Ge/Au/Ni layer, an Al/Ti/Pt/Au layer, or a Cr/Pt/Au layer. In this embodiment, the first electrode 105 is preferably an NGe/Au/Ni layer.

In S104, the epitaxial structure is etched for a first time at a position corresponding to a dicing region to form a first mesa, and side walls of the first conductivity type semiconductor layer and the light-emitting layer are exposed. A surface of the first mesa is the second conductivity type semiconductor layer.

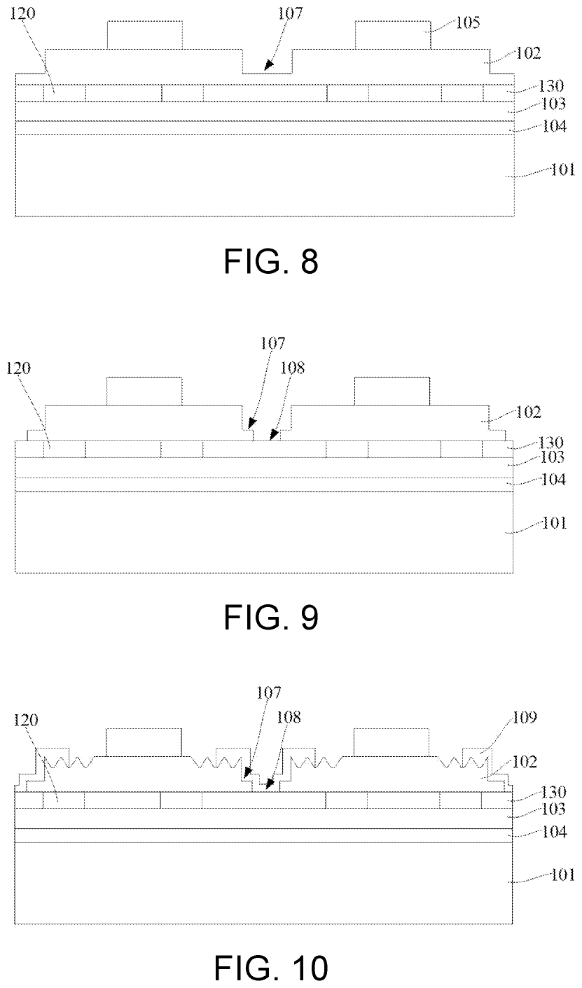

After the epitaxial structure 102 is bonded to the substrate 101, in order to facilitate subsequent dicing to obtain a single LED chip, the epitaxial structure 102 has a corresponding dicing region. A region to be etched in the dicing region is defined by masking. As shown in FIG. 8, the epitaxial structure 102 is etched for the first time in the region to be etched, and in an optional embodiment, dry etching, such as ICP etching, is used to etch the epitaxial structure for the first time. The etching stops in the second conductivity type semiconductor layer 1023, that is, the epitaxial structure 102 is not etched through, and part or all of the second conductivity type semiconductor layer 1023 is retained to form a first mesa 107 as shown in FIG. 8. The first mesa 107 exposes side walls of the first conductivity type semiconductor layer 1021 and the light-emitting layer 1022 in the epitaxial structure 102a, and a surface of the first mesa 107 is the second conductivity type semiconductor layer 1023.

In S105, the epitaxial structure is etched for a second time at the first mesa, a second mesa is formed, and a side wall of the second conductivity type semiconductor layer is exposed.

As shown in FIG. 9, after the first mesa 107 is formed, the epitaxial structure 102 is etched for the second time at the first mesa 107. For instance, the ICP process is still used for the second etching, and etching parameters are adjusted so that an etching width of the second etching is smaller than an etching width of the first etching. This etching etches through the remaining second conductivity type semiconductor layer 1023 until the current blocking layer 130 is exposed, forming a second mesa 108. The second mesa 108 exposes a side wall of the second conductivity type semiconductor layer 1023, and a surface thereof is the current blocking layer 130.

As shown in FIG. 9, the first mesa 107 and the second mesa 108 have a height difference. This structure can effectively reduce internal reflection of large-angle light in the epitaxial structure 102, reduce secondary absorption of light, and improve a side light extraction rate. Especially for small and medium-sized chips, the side light extraction rate may be significantly improved, while the impact of scratching and melting back on brightness may be lowered, and the overall light extraction efficiency may be improved.

In S106, a protective layer is formed on the surface and a side wall of the first mesa, a surface and a side wall of the second mesa, and a surface of the epitaxial structure.

As shown in FIG. 10, after the first mesa 107 and the second mesa 108 are formed, a protective layer 109 is formed on the surface of the structure. The protective layer 109 is formed on the surface and a side wall of the first mesa 107, the surface and a side wall of the second mesa 108, and a surface of the epitaxial structure 102. That is, the protective layer 109 covers all exposed side walls of the first conductivity type semiconductor layer 1021, the light-emitting layer 1022, and the second conductivity type semiconductor layer 1023 and the surface of the first conductivity type semiconductor layer 1021 in the dicing region.

As shown in FIG. 10, before the protective layer 109 is formed, the surface of the epitaxial structure 102 (the first conductivity type semiconductor layer 1021) is also roughened. For instance, a nano-microstructure is formed on the surface of the epitaxial structure 102. In this way, the light extraction rate of the LED chip is improved, and the adhesion of the protective layer 109 is increased.

As shown in FIG. 10, the protective layer 109 covers the surfaces and the side walls of the first mesa 107 and the second mesa 108 and also covers the surface of the epitaxial structure 102 in the dicing region. Further, at the surface of the second mesa 108, the protective layer 109 is in contact with the current blocking layer 130, and a continuous structure is thereby formed. The protective layer 109 forms a continuous protective layer 109 on the surface of the structure shown in FIG. 9, and this continuous protective layer 109 protects the epitaxial structure 102 and the reflective layer 103 by isolating subsequent processing solutions and preventing chemical corrosion.

In S107, a back electrode electrically connected to the second conductivity type semiconductor layer is formed on the back surface of the substrate.

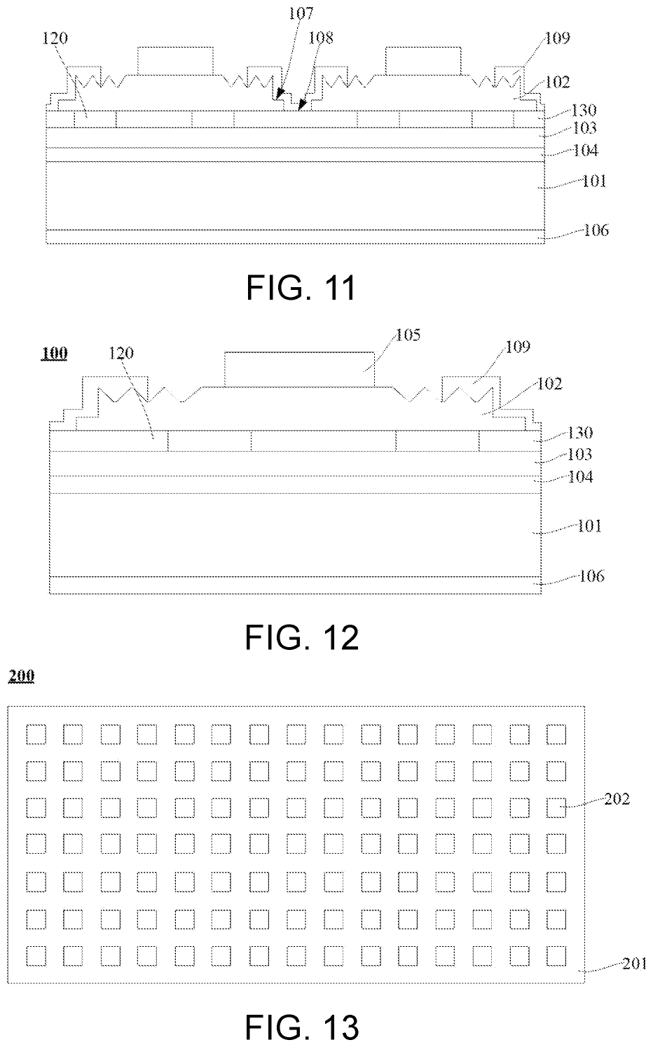

After the protective layer 109 is formed, as shown in FIG. 11, backside metallization is performed on the back surface of the substrate 101 to form a back electrode 106. In order to meet a target thickness requirement, the back of the substrate 101 needs to be thinned first. For instance, the substrate 101 may be thinned to approximately 100 μm by mechanical polishing and then further thinned to approximately 80 μm by polishing. During the polishing process, there may be chemical polishing liquid residue on the back surface of the substrate. A lattice of the polished surface is destroyed and new polishing products are produced, which causes abnormal voltage of the chip. Further, during the polishing process, the surface of the first electrode is coated with a photoresist to protect the first electrode from damage during the polishing process. After polishing, the polished surface needs to be treated and the photoresist on the surface of the first electrode needs to be removed. For example, a KOH solution is used to treat the polished surface. The polished structure is soaked in a photoresist removal solution mixed with sulfuric acid (concentration 98 wt. %) and hydrogen peroxide (concentration 30 wt. %) to remove the photoresist. The structure is then placed in a KOH solution to remove the polishing products on the back surface of the substrate 101 to ensure that the chip has no voltage hazards. After that, the thinned substrate 101 is cleaned with deionized water and dried. As shown in FIG. 11, metal, such as Cu, Au, or Ag, is then deposited on the back surface of the substrate 101 to form the back electrode 106. The back electrode 106 is electrically connected to the second electrode and is used to transmit current to the second conductivity type semiconductor layer 1023.

Due to the formation of the protective layer 109 described in this embodiment, the protective layer 109 may protect the side wall of the epitaxial structure 102 and the reflective layer 103 from being corroded by the KOH solution during the backside metallization process of the substrate 101. In this way, the integrity of the epitaxial structure 102 is ensured, and the reliability of the chip is improved. The method provided by the disclosure does not require the addition of additional process flows and may be implemented by adjusting the process parameters of the relevant processes. Therefore, this method does not cause an increase in costs and is conducive to mass production.

After the structure shown in FIG. 11 is formed, dicing is performed along the second mesa 108. The reflective layer 103, the bonding layer 104, and the substrate 101 are diced through at one time to separate adjacent LED chips. As shown in FIG. 12, an independent LED chip is obtained. As shown in FIG. 12, the epitaxial structure 102 of the diced LED chip is covered by the protective layer 109. The protective layer 109 may effectively protect the epitaxial structure 102 from damage during the dicing process. In subsequent use, the protective layer 109 may also effectively protect the epitaxial structure 102, so that the reliability of the LED chip is effectively improved.

### Embodiment 2

This embodiment provides a vertical LED chip structure. With reference to FIG. 12 again, the vertical LED chip structure 100 includes the substrate 101 and the epitaxial structure 102 bonded to the front surface of the substrate 101. The abovementioned epitaxial structure may be the epitaxial structure shown in FIG. 5A or FIG. 5B in Embodiment 1. Preferably, it is the epitaxial structure shown in FIG. 5B. With reference to FIG. 5B as well, the epitaxial structure 102 includes the first conductivity type semiconductor layer 1021, the light-emitting layer 1022, and the second conductivity type semiconductor layer 1023 stacked in sequence. The side where the second conductivity type semiconductor layer 1023 is located is bonded to the substrate 101. As shown in FIG. 5B as well, the epitaxial structure 102 further includes the second electrode formed on the surface of the second conductivity type semiconductor layer 1023. The second electrode includes the current blocking layer 130 adjacent to the second conductivity type semiconductor layer 1023, the transparent conductive layer 120 formed in the through hole penetrating through the current blocking layer 130, and the reflective layer 103 formed above the current blocking layer 130 and the transparent conductive layer 120. The reflective layer 103 reflects the light radiated by the light-emitting layer 1022 in all directions. The bonding layer 104 located on the surface of the reflective layer 103 is formed, and the bonding layer 104 is a metal bonding layer, such as an Au/Sn metal bonding layer.

With reference to FIG. 12 as well, a nano-microstructure is formed on the surface of the epitaxial structure 102 (the first conductivity type semiconductor layer 1021), so that the surface of the epitaxial structure 102 is formed into a rough surface. The rough surface may improve the light extraction rate of the LED chip and increase the adhesion of the protective layer 109.

The first mesa 107 is formed in the second conductivity type semiconductor layer 1023 corresponding to the dicing region, and the surface of the first mesa 107 is the second conductivity type semiconductor layer 1023. The side wall of the first mesa 107 is the epitaxial structure 102, and the surface is the second conductivity type semiconductor layer 1023.

The second mesa 108 is formed in the first mesa 107. The side wall of the second mesa 108 is the second conductivity type semiconductor layer 1023, and the second mesa 108 penetrates through the second conductivity type semiconductor layer 1023. Preferably, the surface of the second mesa 108 is the current blocking layer 130.

The protective layer 109 is formed on the surface and the side wall of the first mesa 107 and the surface and the side wall of the second mesa 108 and is located on the surface of the epitaxial structure 102 located in the dicing region. The protective layer 109 covers the surfaces and the side walls of the first mesa 107 and the second mesa 108 and also covers the surface of the epitaxial structure 102 in the dicing region. Further, at the surface of the second mesa 108, the protective layer 109 is in contact with the current blocking layer 130, and a continuous structure is thereby formed. The protective layer 109 forms a continuous protective layer 109 on the surface of the LED chip structure, and this continuous protective layer 109 protects the epitaxial structure 102 and the reflective layer 103 by isolating processing solutions and preventing chemical corrosion, so the reliability of the LED chip is effectively improved.

With reference to FIG. 12 and FIG. 5B again, the first electrode 105 is formed above the first conductivity type semiconductor layer 1021 of the epitaxial structure 102. The first electrode 105 may be a Ge/Au/Ni layer, an Al/Ti/Pt/Au layer, or a Cr/Pt/Au layer. In this embodiment, the first electrode 105 is preferably a Ge/Au/Ni layer.

The vertical LED chip structure 100 of this embodiment also includes a back electrode 106. The back electrode 106 is formed on the back surface of the substrate 101 opposite to the front surface and electrically connected to the second conductivity type semiconductor layer.

### Embodiment 3

This embodiment provides a light-emitting device. As shown in FIG. 13, a light-emitting device 200 includes a circuit substrate 201 and a light-emitting unit 202 disposed on the circuit substrate 201. The light-emitting unit 202 may include the vertical LED chip structure 100 according to Embodiment 2 of the disclosure.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A method of fabricating a vertical light-emitting diode (LED) chip structure, comprising:
fabricating an epitaxial structure comprising a first conductivity type semiconductor layer, a light-emitting layer, and a second conductivity type semiconductor layer stacked in sequence;
providing a substrate having a front surface and a back surface opposite to the front surface;
bonding the epitaxial structure to the front surface of the substrate, wherein a side where the second conductivity type semiconductor layer is located is bonded to the substrate;
etching the epitaxial structure for a first time at a position corresponding to a dicing region to form a first mesa and exposing side walls of the first conductivity type semiconductor layer and the light-emitting layer, wherein a surface of the first mesa is the second conductivity type semiconductor layer;
etching the epitaxial structure for a second time at the first mesa to form a second mesa and exposing a side wall of the second conductivity type semiconductor layer;
forming a protective layer on the surface and a side wall of the first mesa, a surface and a side wall of the second mesa, and a surface of the epitaxial structure; and
forming a back electrode electrically connected to the second conductivity type semiconductor layer on the back surface of the substrate.

2. The method of fabricating the vertical LED chip structure according to claim 1, wherein the fabricating the epitaxial structure further comprises the following steps:
providing a temporary substrate;
depositing the first conductivity type semiconductor layer, the light-emitting layer, and the second conductivity type semiconductor layer in sequence on a front surface of the temporary substrate;
forming a second electrode comprising a current blocking layer and a transparent conductive layer adjacent to the second conductivity type semiconductor layer above the second conductivity type semiconductor layer and forming a reflective layer above the current blocking layer and the transparent conductive layer, wherein the transparent conductive layer is formed in a through hole penetrating through the current blocking layer and is in contact with the second conductivity type semiconductor layer; and
forming a bonding layer above the reflective layer.

3. The method of fabricating the vertical LED chip structure according to claim 1, wherein the forming the back electrode on the back surface opposite to the front surface of the substrate further comprises the following steps:
applying a polishing slurry to the back surface of the substrate and masking and thinning the back surface of the substrate;
cleaning the thinned substrate with deionized water and drying the substrate; and
depositing a metal layer on the back surface of the substrate to form the back electrode.

4. The method of fabricating the vertical LED chip structure according to claim 2, wherein the surface of the second mesa is the current blocking layer, and the protective layer covers the current blocking layer and forms a continuous structure with the current blocking layer at the second mesa.

5. The method of fabricating the vertical LED chip structure according to claim 1, wherein after the bonding the epitaxial structure to the front surface of the substrate, the method further comprises: forming a first electrode above the first conductivity type semiconductor layer.

6. The method of fabricating the vertical LED chip structure according to claim 1, wherein after the second mesa is formed, a surface of the first conductivity type semiconductor layer away from the light-emitting layer is roughened.

7. The method of fabricating the vertical LED chip structure according to claim 1, further comprising: dicing the substrate along the second mesa to obtain independent LED chips.

8. A vertical light-emitting diode (LED) chip structure, comprising:
a substrate having a front surface and a back surface opposite to the front surface;
an epitaxial structure located on the front surface of the substrate and comprising a first conductivity type semiconductor layer, a light-emitting layer, and a second conductivity type semiconductor layer stacked in sequence, wherein a side where the second conductivity type semiconductor layer is located is bonded to the substrate;
a first mesa formed in the second conductivity type semiconductor layer corresponding to a dicing region, wherein a surface of the first mesa is the second conductivity type semiconductor layer;
a second mesa formed in the first mesa;
a protective layer formed on the surface and a side wall of the first mesa, a surface and a side wall of the second mesa, and a surface of the first conductivity type semiconductor layer located in the dicing region; and
a back electrode formed on the back surface of the substrate and electrically connected to the second conductivity type semiconductor layer.

9. The vertical LED chip structure according to claim 8, further comprising a first electrode formed above the first conductivity type semiconductor layer.

10. The vertical LED chip structure according to claim 8, further comprising:
a second electrode formed on a side of the second conductivity type semiconductor layer away from the light-emitting layer and comprising a current blocking layer and a transparent conductive layer adjacent to the second conductivity type semiconductor layer and a reflective layer covering the current blocking layer and the transparent conductive layer, wherein the transparent conductive layer is formed in a through hole penetrating through the current blocking layer and is in contact with the second conductivity type semiconductor layer; and
a bonding layer covering the reflective layer and bonding the epitaxial structure to the substrate.

11. A light-emitting device, comprising a circuit substrate and a light-emitting unit located on the circuit substrate, wherein the light-emitting unit comprises the vertical LED chip structure according to claim 8.
